(19) United States
(12) Patent Application Publication
(10) Pub. No.: US 2011/0193235 A1
(43) Pub. Date: Aug. 11, 2011

(54) 3DIC Architecture with Die Inside Interposer

(75) Inventors: Hsien-Pin Hu, Zhubei City (TW); Chen-Hua Yu, Hsin-Chu (TW); Jiun Ren Lai, Zhubei City (TW); Ming-Fa Chen, Taichung City (TW)

(73) Assignee: Taiwan Semiconductor Manufacturing Company, Ltd., Hsin-Chu (TW)

(21) Appl. No.: 12/775,186

(22) Filed: May 6, 2010

Related U.S. Application Data
(60) Provisional application No. 61/301,832, filed on Feb. 5, 2010.

(51) Int. Cl. H01L 23/538

(52) U.S. Cl. 257/773; 257/E23.174

(57) ABSTRACT

A device is formed to include an interposer having a top surface, and a bump on the top surface of the interposer. An opening extends from the top surface into the interposer. A first die is bonded to the bump. A second die is located in the opening of the interposer and bonded to the first die.

This application claims the benefit of U.S. Provisional Application No. 61/301,832 filed on Feb. 5, 2010, entitled “More than 2D,” which application is hereby incorporated herein by reference.

### TECHNICAL FIELD

This disclosure relates generally to integrated circuits, and more particularly to three-dimensional integrated circuits (3DICs) comprising silicon interposers and the method of forming the same.

### BACKGROUND

Since the invention of integrated circuits, the semiconductor industry has experienced continuous rapid growth due to constant improvements in the integration density of various electronic components (i.e., transistors, diodes, resistors, capacitors, etc.). For the most part, these improvements in integration density have come from repeated reductions in minimum feature size, allowing more components to be integrated into a given chip area.

These integration improvements are essentially two-dimensional (2D) in nature, in that the volume occupied by the integrated components is essentially on the surface of the semiconductor wafer. Although dramatic improvements in lithography have resulted in considerable improvements in 2D integrated circuit formation, there are physical limitations to the density that can be achieved in two dimensions. One of these limitations is the minimum size needed to make these components. Also, when more devices are put into one chip, more complex designs are required. An additional limitation comes from the significant increase in the number and length of interconnections between devices as the number of devices increases. When the number and length of interconnections increase, both circuit RC delay and power consumption increase.

Three-dimensional integrated circuits (3DICs) were thus formed, wherein two dies may be stacked, with through-silicon vias (TSVs) formed in one of the dies to connect the other die to a package substrate. The TSVs are often formed after the front-end-of-line (FEOL) process, in which devices, such as transistors, are formed, and possibly after the back-end-of-line (BEOL) process, in which the interconnect structures are formed. This may cause yield loss of the already formed dies. Further, since the TSVs are formed after the formation of integrated circuits, the cycle time for manufacturing is also prolonged.

### SUMMARY

In accordance with one aspect, a device is formed to include an interposer having a top surface, and a bump on the top surface of the interposer. An opening extends from the top surface into the interposer. A first die is bonded to the bump. A second die is located in the opening of the interposer and bonded to the first die.

Other embodiments are also disclosed.

### BRIEF DESCRIPTION OF THE DRAWINGS

For a more complete understanding of the embodiments, and the advantages thereof, reference is now made to the following descriptions taken in conjunction with the accompanying drawings, in which:

FIGS. 1 through 10 are cross-sectional views and a top view of intermediate stages in the manufacturing of a three-dimensional package comprising dies bonded to an interposer in accordance with various embodiments.

### DETAILED DESCRIPTION OF ILLUSTRATIVE EMBODIMENTS

The making and using of the embodiments of the disclosure are discussed in detail below. It should be appreciated, however, that the embodiments provide many applicable inventive concepts that can be embodied in a wide variety of specific contexts. The specific embodiments discussed are merely illustrative and do not limit the scope of the disclosure.

A novel three-dimensional integrated circuit (3DIC) and the method of forming the same are provided. The intermediate stages of manufacturing an embodiment are illustrated. The variations of the embodiment are discussed. Throughout the various views and illustrative embodiments, like reference numbers are used to designate like elements.

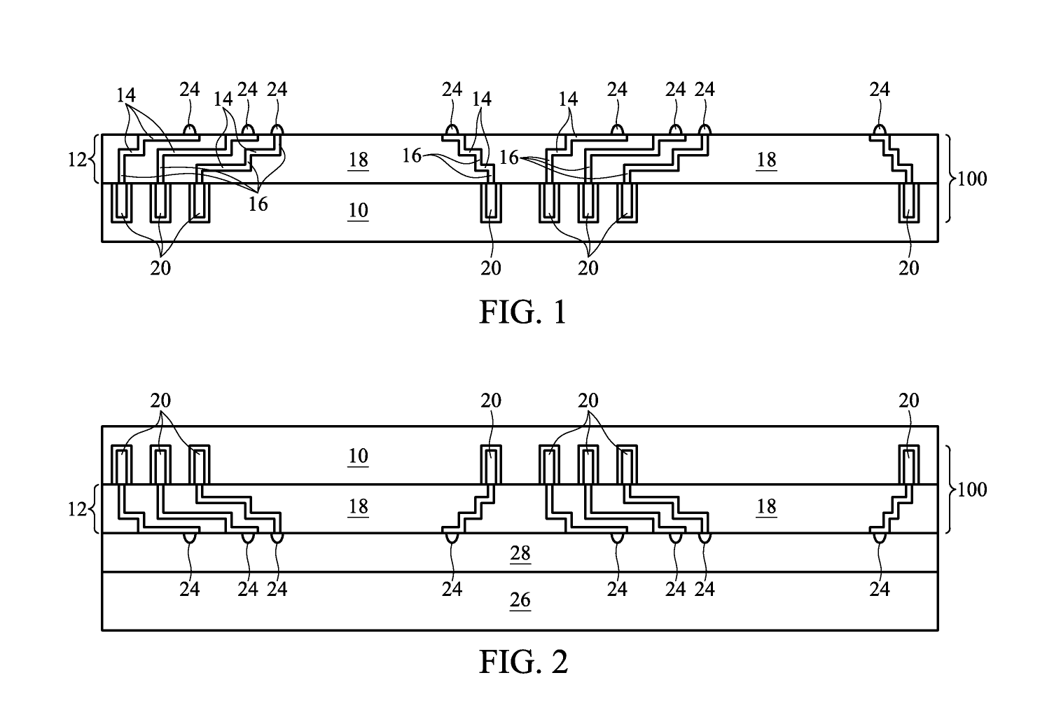

Referring to FIG. 1, substrate 10 is provided. Throughout the description, substrate 10 and the overlying and underlying interconnect structures in combination are referred to as interposer wafer 100. Substrate 10 may be formed of a semiconductor material, such as silicon, silicon germanium, silicon carbide, gallium arsenide, or other semiconductor materials. Alternatively, substrate 10 is formed of a dielectric material, such as silicon oxide. Interposer wafer 100 is substantially free from integrated circuit devices, including active devices, such as transistors and diodes. Furthermore, interposer wafer 100 may include, or may be free from, passive devices, such as capacitors, resistors, inductors, varactors, or the like.

Interconnect structure 12 is formed over substrate 10. Interconnect structure 12 includes one or more dielectric layer 18, and metal lines 14 and vias 16 in dielectric layers 18. Throughout the description, the side of interposer wafer 100 facing up in FIG. 1 is referred to as a front side and the side facing down is referred to as a back side. Metal lines 14 and vias 16 are referred to as front-side redistribution lines (RDLs). Further, through-substrate vias (TSVs) 20 are formed in substrate 10 and may possibly penetrate some or all of dielectric layer 18. TSVs 20 are electrically coupled to front-side RDLs 14/16.

Next, front-side (metal) bumps 24 are formed on the front-side of interposer wafer 100 and are electrically coupled to TSVs 20 and RDLs 14/16. In an embodiment, metal bumps 24 are solder bumps, such as eutectic solder bumps. In alternative embodiments, front-side bumps 24 are copper bumps or other metal bumps formed of gold, silver, nickel, tungsten, aluminum, and/or alloys thereof.

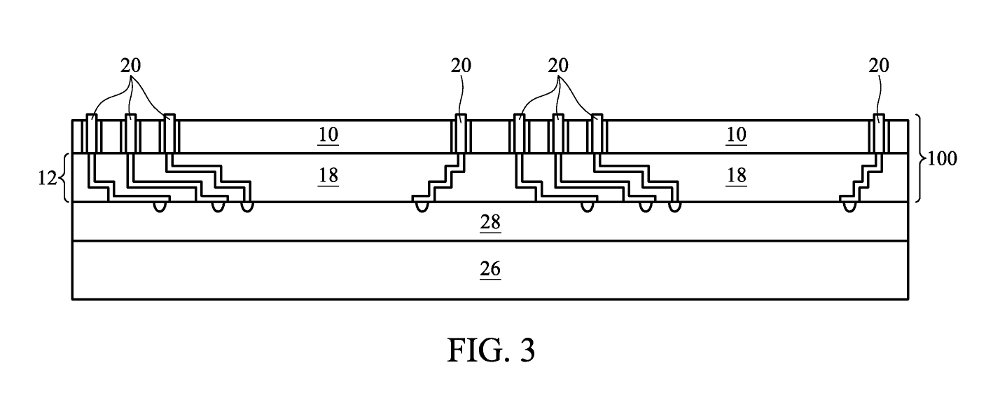

Referring to FIG. 2, carrier 26, which may be a glass wafer, is bonded on the front side of interposer wafer 100 through adhesive 28. Adhesive 28 may be an ultra-violet (UV) glue, or may be formed of other known adhesive materials. In FIG. 3, a wafer backside grinding is performed to thin substrate 10 from the backside until TSVs 20 are exposed. An etch may be performed to remove more of substrate 10 so that TSVs 20 protrude slightly out of the back surface of the remaining portion of substrate 10.

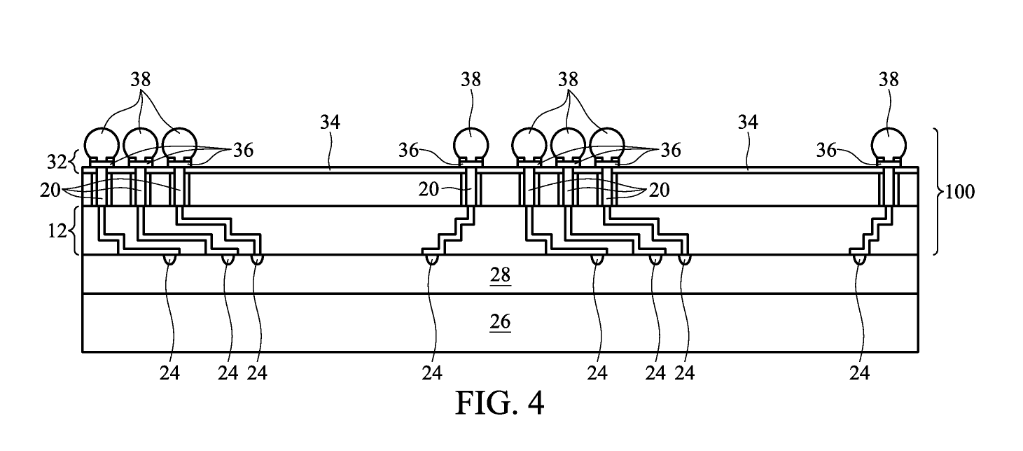

Next, as shown in FIG. 4, backside interconnect structure 32 is formed to connect to TSVs 20. In various embodiments, backside interconnect structure 32 may have a similar structure as front-side interconnect structure 12, and may include metal bumps and one or more layer of RDLs. For example, backside interconnect structure 32 may include dielectric layer 34 on substrate 10, wherein dielectric layer 34 may be a low-temperature polyimide layer, or may be formed of commonly known dielectric materials, such as spin-on glass, silicon oxide, silicon oxynitride, or the like. Dielectric layer 34 may also be formed of chemical vapor deposition (CVD). When the low-temperature polyimide is used, dielectric layer 34 also acts as a stress buffer layer. Under-bump metallurgy (UBM) 36 and backside metal bumps 38 may then be formed. Similarly, backside metal bumps 38 may be solder bumps, such as eutectic solder bumps, copper bumps, or other metal bumps formed of gold, silver, nickel, tungsten, aluminum, and/or alloys thereof. In an exemplary embodiment, the formation of UBM 36 and bumps 38 may include blanket forming a UBM layer (not shown), forming a mask (not shown) over the UBM layer, with openings (not shown) formed in the mask, plating bumps 38 in the openings, removing the mask, and performing a flash etching to remove the portions of the blanket UBM layer previously covered by the mask. The remaining portions of the UBM layer are UBM 36.

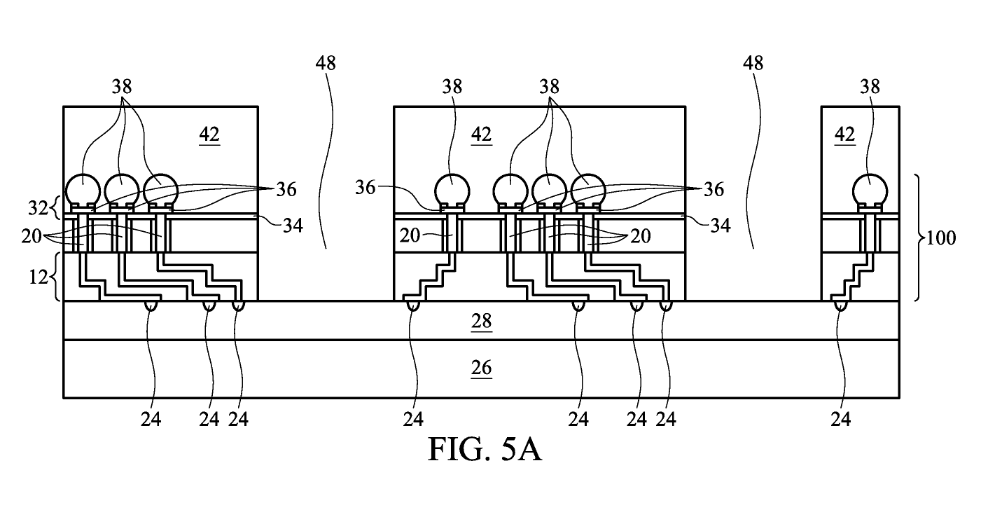

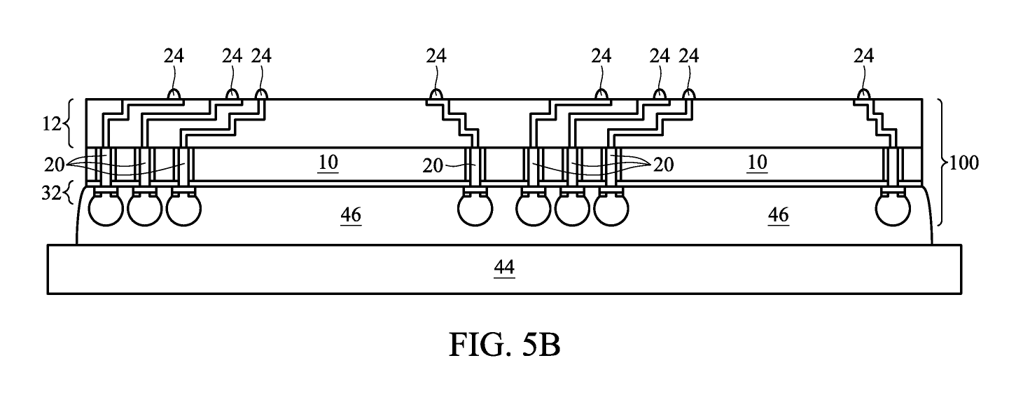

Referring to FIG. 5A, openings 48 are formed in interposer wafer 100, for example, using a wet etch or a dry etch. This may be performed by forming and patterning photo resist 42 and then etching interposer wafer 100 through openings in photo resist 42. The etch may stop when adhesive 28 is reached. Next, photo resist 42 is removed.

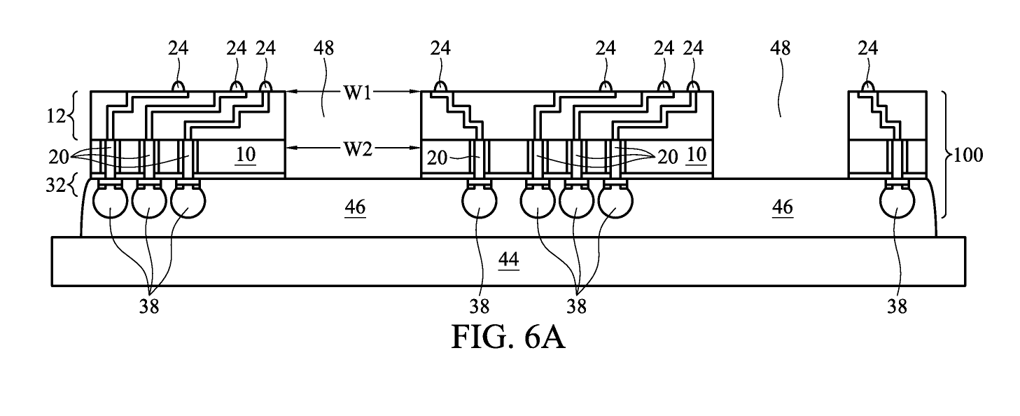

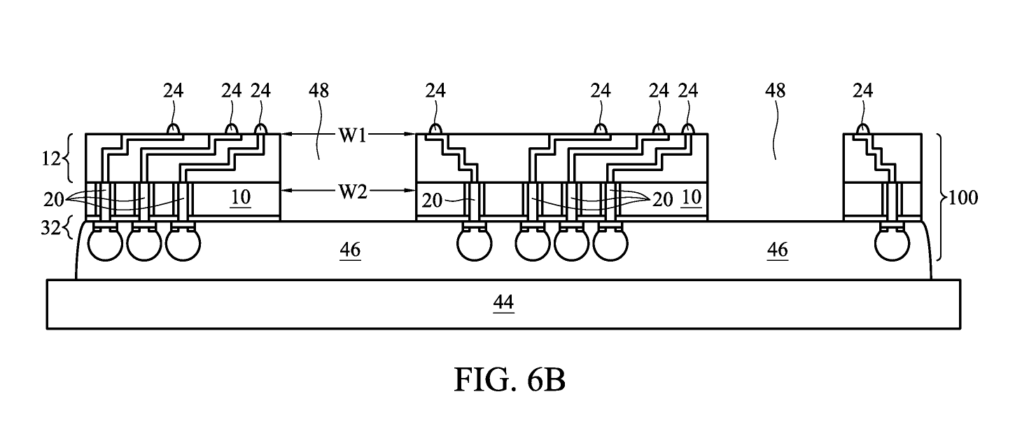

In FIG. 6A, carrier 26 is de-bonded, for example, by exposing UV glue 28 to a UV light, causing it to lose its adhesive property. Interposer wafer 100 is then further bonded to carrier 44. However, this time, the backside of interposer wafer 100 is bonded to carrier 44 and possibly adhered to UV glue 46. The backside of interposer wafer 100 is exposed and cleaned. Front-side bumps 24 are thus exposed.

In alternative embodiments, as shown in FIGS. 5B and 6B, the order of the process steps as shown in FIGS. 5A and 6A is reversed. Referring to FIG. 5B, after the structure as shown in FIG. 4 is formed, carrier 26 is de-bonded from the front-side of interposer wafer 100, and then carrier 44 is bonded to the backside of interposer wafer 100. Next, as shown in FIG. 6B, an etch is performed from the front-side of interposer wafer 100 to form openings 48. The structures shown in FIGS. 6A and 6B are very similar to each other, although they may be distinguished from each other since the etching for forming openings 48 is performed from different sides of interposer wafer 100. Accordingly, in FIG. 6A, dimension W1, which is a dimension of opening 48 at a location close to the front-side of interposer wafer 100, may be greater than dimension W2, which is a dimension of opening 48 at a location close to the backside of interposer wafer 100. However, in FIG. 6B, dimension W1 may be greater than dimension W2.

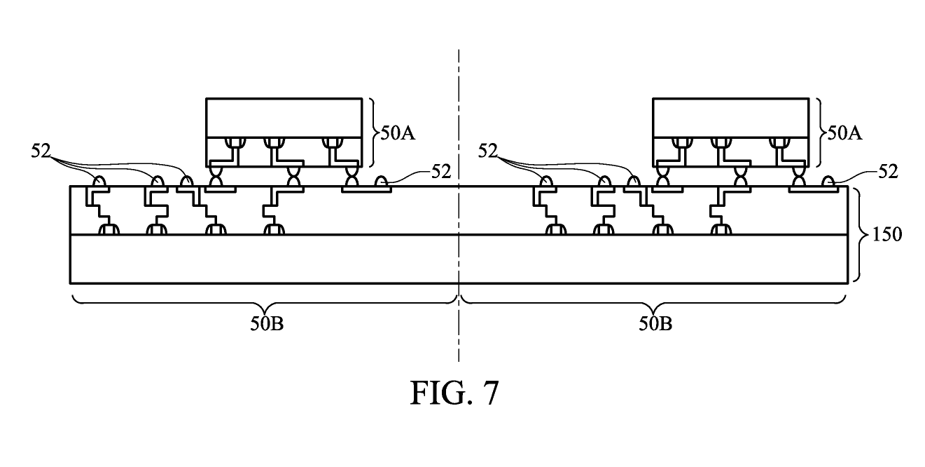

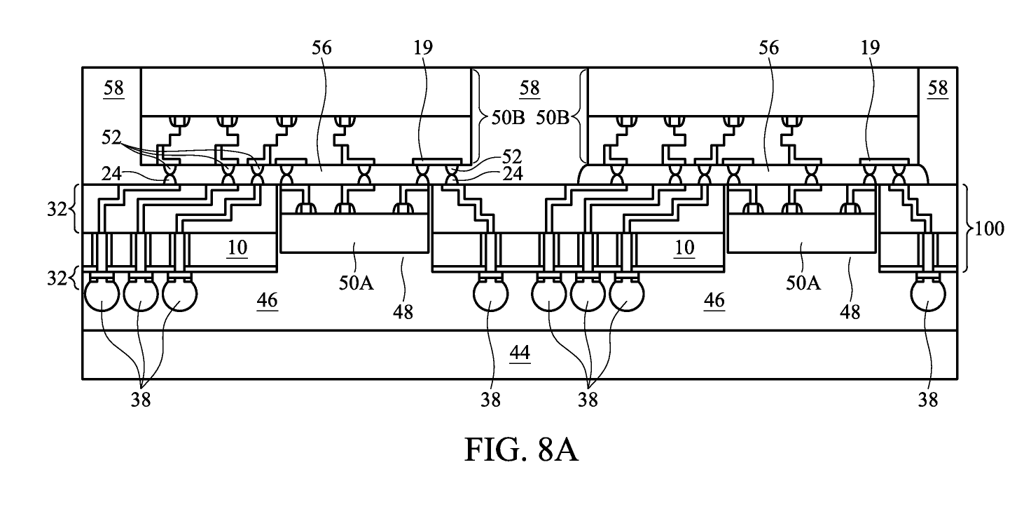

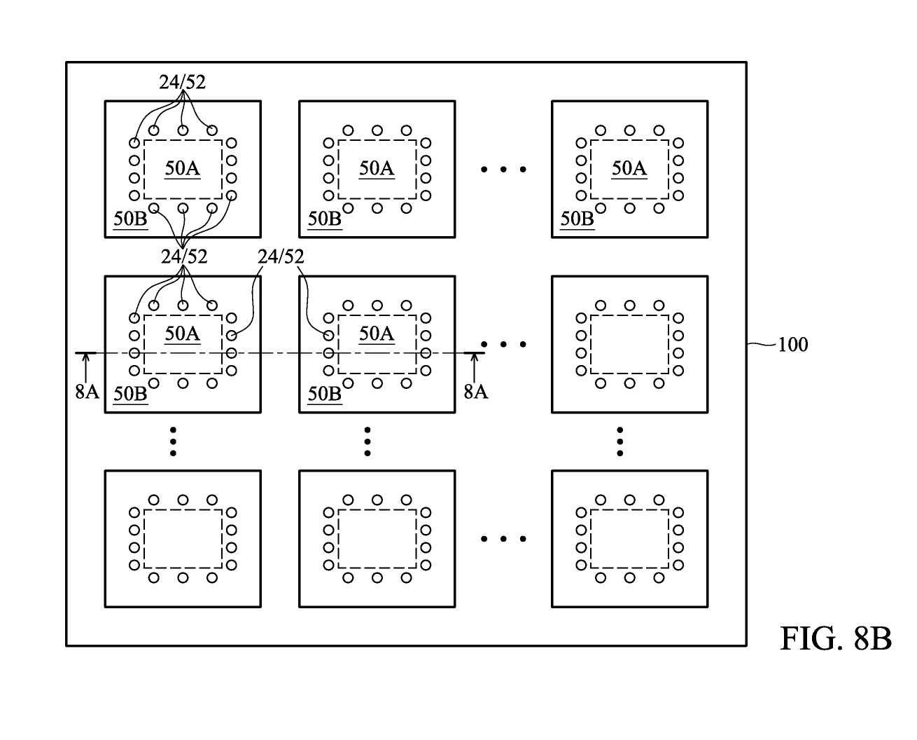

In subsequent process steps (FIGS. 8A and 8B), stack-die structure 50, which includes die 50A and die 50B, is bonded to the structure shown in FIG. 6A or 6B. A cross-sectional view of an intermediate stage in the formation of stack-die structure 50 is shown in FIG. 7. First, wafer 150 is provided, which includes chips 50B therein. Dies 50A are then bonded to chips 50B using a die-to-wafer bonding process. Dies 50A and 50B may be device dies comprising integrated circuit devices, such as transistors (as schematically illustrated), capacitors, inductors, resistors, and the like, therein. The bonding between dies 50A and chips 50B may be a solder bonding or a metal-to-metal bonding. A die-saw is then performed to separate the structure shown in FIG. 7 into a plurality of stack-die structures 50, each including one of dies 50A and one of chips 50B (chips 50B may be referred to as dies after being sawed), wherein dies 50A have (horizontal) sizes smaller than that of dies 50B. In the resulting structure, bond pads or bumps 52 (referred to as bumps hereinafter) are on the surfaces of dies 50B and facing dies 50A, and are not covered by the respective dies 50A. Dies 50A are bonded to center portions of the respective dies 50B, while edge portions of dies 50B may be bonded to interposer wafer 100. Again, depending on the type of front-side bumps 24 (FIG. 6A or 6B), bumps 52 may be bond pads, solder bumps, or other non-reflowable metal bumps, such as copper bumps.

FIG. 8A illustrates the bonding of stack-die structures 50 onto interposer wafer 100, wherein dies 50A are inserted into openings 48, and a bonding is performed to bond stack-die structures 50 to interposer wafer 100, with bumps 52 being bonded to front-side bumps 24. FIG. 8B illustrates a top view of the structure shown in FIG. 8A, wherein the cross-sectional view shown in FIG. 8A is obtained from the vertical plane crossing line 8A-8A in FIG. 8B. It is observed that the bonds formed of front-side bumps 24 and bumps 52 may surround dies 50A. Dies 50A are bonded to interposer wafer 100 through flip-chip bonding, and dies 50B are also bonded to interposer wafer 100 through flip-chip bonding. Through such a bonding scheme, not only dies 50A are electrically coupled to dies 50B and backside bumps 38, dies 50A may also be electrically coupled to backside bumps 38, for example, through connection 19 in die 50B and the respective bumps 24 and 52. Accordingly, no TSV is needed/formed (although they may be formed) in any of dies 50A and 50B, while the devices in dies 50A and 50B may all be electrically coupled to backside bumps 38.

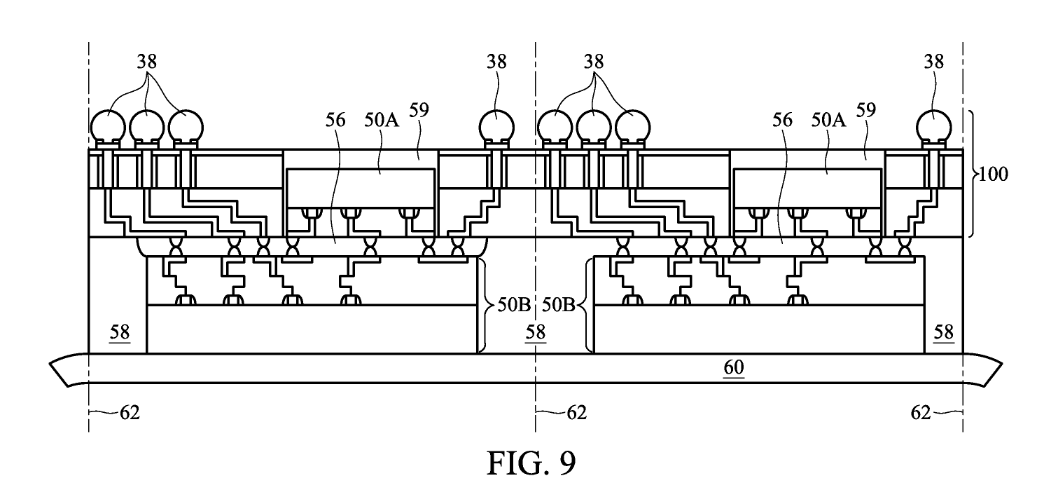

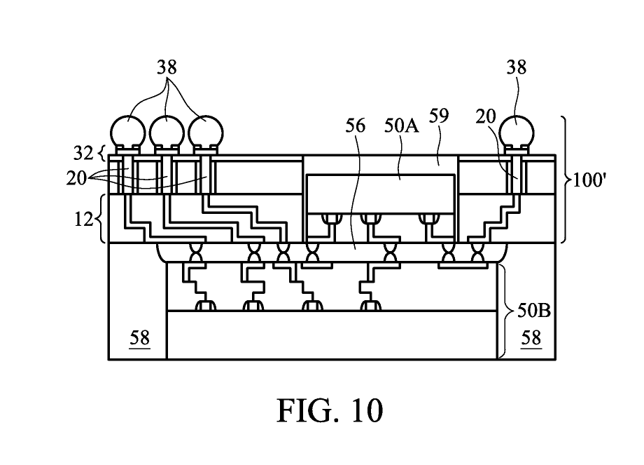

As also shown in FIG. 8A, underfill 56 may be filled into the gaps between dies 50B and interposer wafer 100. Molding compound 58 may be applied into the gaps between dies 50B and may be planarized to form a planar surface. In FIG. 9, carrier 44 is de-bonded. Underfill or molding compound 59 may then be filled into the gaps between dies 50A and interposer wafer 100. Next, dicing tape 60 is adhered to the front side of the resulting structure, which has been planarized. A dicing is then performed along lines 62 to separate interposer wafer 100 and dies 50A/50B into a plurality of dies. A resulting structure is shown in FIG. 10, wherein the resulting die includes one of interposer die 100′, die 50A, and die 50B.

It is observed that in the structure shown in FIG. 10, no TSVs are necessary, although they can be formed, in any of dies 50A and 50B. However, the devices in both dies 50A and 50B may be electrically coupled to backside bumps 38. In conventional 3DICs, the formation of TSVs is formed after the device dies are formed. This results in the increase in the yield loss and the cycle time for packaging. In the embodiments, however, no TSVs are needed, and the possible yield loss resulting from the formation of TSVs is avoided. Further, the cycle time is reduced since interposer wafer 100 can be formed separately from the formation of dies 50A and 50B.

Although the embodiments and their advantages have been described in detail, it should be understood that various changes, substitutions, and alterations can be made herein without departing from the spirit and scope of the embodiments as defined by the appended claims. Moreover, the scope of the present application is not intended to be limited to the particular embodiments of the process, machine, manufacture, and composition of matter, means, methods and steps described in the specification. As one of ordinary skill in the art will readily appreciate from the disclosure, processes, machines, manufacture, compositions of matter, means, methods, or steps, presently existing or later to be developed, that perform substantially the same function or achieve substantially the same result as the corresponding embodiments described herein may be utilized according to the disclosure. Accordingly, the appended claims are intended to include within their scope such processes, machines, manufacture, compositions of matter, means, methods, or steps. In addition, each claim constitutes a separate embodiment, and the combination of various claims and embodiments are within the scope of the disclosure.

What is claimed is:

1. A device comprising:
an interposer comprising a top surface;
a first bump on the top surface of the interposer;
an opening extending from the top surface into the interposer;
a first die bonded to the first bump; and
a second die bonded to the first die and in the opening.

2. The device of claim 1, wherein the interposer comprises a silicon substrate, and is substantially free from integrated circuit devices.

3. The device of claim 1, wherein the interposer comprises a dielectric substrate.

4. The device of claim 1 further comprising a second bump at a bottom surface of the interposer opposite the top surface.

5. The device of claim 4, wherein the second bump is electrically coupled to the second die.

6. The device of claim 1, wherein the interposer comprises:
a substrate;
through-substrate vias (TSVs) in the substrate; and
redistribution lines on opposite sides of the substrate and electrically coupled to the TSVs.

7. The device of claim 1 further comprising a molding compound over the interposer and comprising a portion encircling the first die.

8. A device comprising:
an interposer substantially free from integrated circuit devices, wherein the interposer comprises:
a silicon substrate;
through-substrate vias (TSVs) in the silicon substrate;
a first plurality of bumps on a first surface of the interposer; and
a second plurality of bumps on a second surface of the interposer opposite the first surface;
a first die bonded to the first plurality of bumps of the interposer; and
a second die bonded to the first die and located in an opening in the interposer.

9. The device of claim 8, wherein the second die has a horizontal size smaller than the first die.

10. The device of claim 8, wherein the first plurality of bumps are distributed encircling the first die.

11. The device of claim 8, wherein the second die is electrically coupled to one of the second plurality of bumps through one of the first plurality of bumps.

12. The device of claim 8 further comprising redistribution lines on opposite sides of the silicon substrate and electrically coupled to the TSVs, the first plurality of bumps, and the second plurality of bumps.

13. The device of claim 8, wherein the opening penetrates the silicon substrate.

14. A device comprising:
an interposer substantially free from integrated circuit devices, wherein the interposer comprises:
a substrate;
dielectric layers on opposite sides of the substrate;
redistribution lines in the dielectric layers and on the opposite sides of the substrate;
through-substrate vias (TSVs) in the substrate and electrically coupled to the redistribution lines; and
an opening penetrating through the substrate and the dielectric layers; and
a first die in the opening and electrically coupled to one of the TSVs.

15. The device of claim 14 further comprising a second die bonded to the first die and the interposer.

16. The device of claim 15, wherein the first die is bonded to bumps at a center portion of the second die, and the interposer is bonded to bumps on an edge portion of the second die.

17. The device of claim 15, wherein the first and the second dies are free from TSVs.

18. The device of claim 14, wherein the substrate is a silicon substrate.
